(19) United States
(12) Patent Application Publication
(10) Pub. No.: US 2012/0241874 A1
(43) Pub. Date: Sep. 27, 2012

(54) GATE OXIDE FILM INCLUDING A NITRIDE LAYER DEPOSITED THEREON AND METHOD OF FORMING THE GATE OXIDE FILM

(76) Inventors: BYUNG-DONG KIM, Seoul (KR); Ja-Hum Ku, Seongnam-City (KR)

(21) Appl. No.: 13/071,883

(22) Filed: Mar. 25, 2011

(51) Int. Cl. H01L 29/772; H01L 21/28

(52) U.S. Cl. 257/411; 438/591; 257/E21.158; 257/E29.242

(57) ABSTRACT

A method for forming a gate stack of a semiconductor device comprises depositing a gate oxide layer on a channel region of a semiconductor substrate using chemical vapor deposition, atomic layer deposition or molecular layer deposition, depositing a nitride layer on the gate oxide layer, oxidizing the deposited nitride layer, depositing a high-K dielectric layer on the oxidized nitride layer, and forming a metal gate on the high-K dielectric layer.

### BACKGROUND

1. Technical Field

The present disclosure relates to a method of forming a gate oxide film, and, more specifically, to a gate oxide film including a nitride layer deposited thereon.

2. Discussion of the Related Art

Field Effect Transistors (FETs), such as NFET and PFET devices are commonly found in Complimentary Metal Oxide Semiconductor (CMOS) devices. In a MOSFET device, a gate electrode, or gate, may include doped polysilicon or a metal conductor formed above an insulator or gate dielectric, such as a gate oxide layer. A gate electrode stack also includes a semiconductor layer or substrate, on which the gate oxide layer is formed. The area in the substrate below the gate oxide layer is a channel region, and a pair of source/drain regions is formed in the substrate on either side of the channel region.

In semiconductor processing, silicon (Si) has been used a substrate material. Silicon germanium (SiGe) has been used as an alternative to silicon to result in a transistor that switches faster and yields higher performance. For example, SiGe may be used in high frequency applications, and the SiGe process is introduced to enhance PMOS performance of nano devices.

SiGe has a larger lattice constant than Si and is more likely than Si to become dislocated when oxidized. As a result, alternatives to oxidation processes on SiGe surfaces are used.

Therefore, there is a need for a gate stack structure that allows the use of oxide films deposited by alternatives to oxidation processes, but also exhibits good reliability characteristics, and is not vulnerable to cleaning and rework processes.

### SUMMARY

A method for forming a gate stack of a semiconductor device, according to an embodiment of the inventive concept, comprises depositing a gate oxide layer on a channel region of a semiconductor substrate using chemical vapor deposition or atomic layer deposition or molecular layer deposition, depositing a nitride layer on the gate oxide layer, oxidizing the deposited nitride layer, depositing a high-K dielectric layer on the oxidized nitride layer, and forming a metal gate on the high-K dielectric layer.

The method may further include annealing the gate oxide layer prior to depositing the nitride layer. The nitride layer may be deposited through plasma enhanced chemical vapor deposition (PECVD), low pressure chemical vapor deposition (LPCVD), atmospheric pressure chemical vapor deposition (APCVD), or atomic layer deposition (ALD). The nitride layer may include one of SiN or SiHN. A nitrogen density of the nitride layer may be about 10¹⁵/cm².

The semiconductor substrate may be made of at least one of silicon (Si) and silicon germanium (SiGe). A breakdown voltage of the gate oxide layer including the oxidized nitride layer thereon may increase from about 6.5 volts to about 10 volts over a range of inversion thickness. A thickness of the gate oxide layer may be less than about 30 angstroms.

The method may also include performing nitridation on the gate oxide layer after deposition of the gate oxide layer.

A gate stack of a semiconductor device, according to an embodiment of the inventive concept, comprises a chemical vapor deposition (or atomic layer deposition or molecular layer deposition) gate oxide layer on a channel region of a semiconductor substrate, an oxidized nitride layer on the gate oxide layer, a high-K dielectric layer on the oxidized nitride layer, and a metal gate on the high-K dielectric layer.

A semiconductor device, according to an embodiment of the inventive concept, comprises a chemical vapor deposition (or atomic layer deposition or molecular layer deposition) gate oxide layer on a channel region of a semiconductor substrate, an oxidized nitride layer on the gate oxide layer, a high-K dielectric layer on the oxidized nitride layer, and a metal gate on the high-K dielectric layer.

A computer system comprising the semiconductor device may be a personal computer (PC), a personal digital assistant (PDA), an MP3 player, a digital audio recorder, a pen-shaped computer, a digital camera, or a video recorder.

A system for transmitting or receiving data, according to an embodiment of the inventive concept, comprises a device for storing a program, and a processor in communication with the device, wherein the device comprises a chemical vapor deposition (or atomic layer deposition or molecular layer deposition) gate oxide layer on a channel region of a semiconductor substrate, an oxidized nitride layer on the gate oxide layer, a high-K dielectric layer on the oxidized nitride layer, and a metal gate on the high-K dielectric layer.

The system may comprise at least one of a mobile system, a portable computer, a web tablet, a mobile phone, a digital music player, or a memory card.

A semiconductor memory card, according to an embodiment of the present inventive concept, comprises an interface part that interfaces with an external device, a controller that communicates with the interface part and a semiconductor device via address and data buses, wherein the semiconductor device comprises a chemical vapor deposition (or atomic layer deposition or molecular layer deposition) gate oxide layer on a channel region of a semiconductor substrate, an oxidized nitride layer on the gate oxide layer, a high-K dielectric layer on the oxidized nitride layer, and a metal gate on the high-K dielectric layer.

### BRIEF DESCRIPTION OF THE DRAWINGS

Exemplary embodiments of the present inventive concept will be described below in more detail, with reference to the accompanying drawings, of which:

FIG. 1 is a cross-sectional view of a metal oxide film;

FIG. 2 is a flow chart showing a method for forming a metal oxide film;

FIG. 3 is a graph showing thickness loss data due to photo rework on a CVD oxide film;

FIG. 4 is a flow chart showing a method for forming a metal oxide film according to an embodiment of the present inventive concept;

FIG. 5 is a cross-sectional view of a metal oxide film according to an embodiment of the present inventive concept;

FIG. 6 is a graph showing breakdown voltage (V_{bd}) versus inversion thickness (Tᵢₙᵥ) of different CVD oxide films, including a CVD oxide film formed in accordance with an embodiment of the present inventive concept;

FIG. 7 is a flow chart showing a method for forming a metal oxide film according to another embodiment of the present inventive concept;

FIG. 8 is a block diagram of a memory card having a semiconductor device including a metal oxide film according to an embodiment of the inventive concept;

FIG. 9 is a block diagram of an information processing system using a semiconductor device including a metal oxide film according to an embodiment of the inventive concept; and

FIG. 10 is a block diagram of an electronic device including a semiconductor device having a metal oxide film according to exemplary embodiments of the present inventive concept.

### DETAILED DESCRIPTION OF THE EMBODIMENTS

Exemplary embodiments of the present inventive concept now will be described more fully hereinafter with reference to the accompanying drawings. This inventive concept may, however, be embodied in many different forms and should not be construed as limited to the embodiments set forth herein.

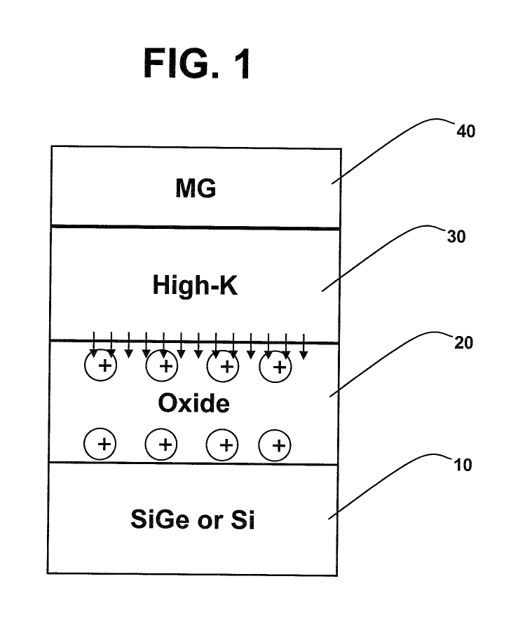

Referring to FIG. 1, a channel region of a substrate 10 includes an oxide 20 formed thereon, a high-K dielectric film 30 formed on the oxide 20, and a metal gate 40 formed on the high-K film 30.

A film deposited on the SiGe substrate by chemical vapor deposition (CVD), atomic layer deposition (ALD) or molecular layer deposition (MLD) (referred to herein as a “CVD film” or “CVD oxide film”; “ALD film” or “ALD oxide film”; “MLD film” or “MLD oxide film”), instead of by an oxidation process, is used as an alternative film to a thermal oxide film.

On one hand, deposition of a CVD/ALD/MLD film can prevent oxidation of the SiGe substrate. However, a CVD/ALD/MLD film may exhibit degraded reliability. In order to compensate for the degraded reliability, a thicker CVD/ALD/MLD film and additional annealing can be used to bolster the film's breakdown characteristics. However, while reliability may be improved by using a thicker CVD/ALD/MLD film, inversion thickness is also increased. As a result, a nitrogen incorporation process (e.g., nitridation) is introduced to reduce inversion thickness. When nitrogen having a relatively high dielectric constant is added to the CVD/ALD/MLD film, the capacitance increases, and performance, which is proportional to capacitance, also increases.

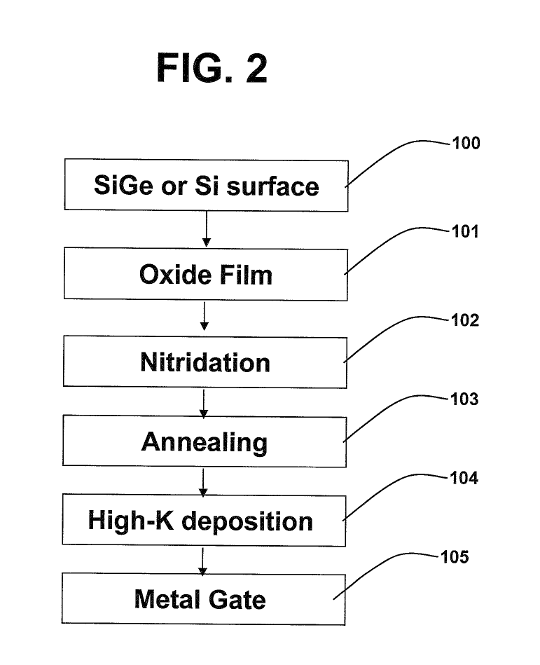

Referring to FIG. 2, a nitridation process 102 (e.g., rapid thermal nitridation (RTN), furnace nitridation, remote plasma nitridation (RPN), decoupled plasma nitridation (DPN)) may be performed after forming the oxide film 101, for example, by CVD/ALD/MLD film deposition, on the Si or SiGe surface 100, and prior to annealing 103. Referring to FIG. 1, the addition of nitrogen to the oxide film 20 may reduce inversion thickness, but the nitridation also generates interface charges (shown by the + signs) at the interface points between the oxide film and the layers on its upper and lower surfaces, and causes device reliability degradation.

The interface charges occur at the interface between the oxide film 20 and the substrate 10 and at the interface between the oxide film 20 and a high-K dielectric film 30. Referring to FIGS. 1 and 2, high-K film deposition 104 occurs after annealing 103, and prior to metal gate formation 105. The high-K dielectric film 30 is a high dielectric constant material (compared to, for example, silicon dioxide) which can enable further miniaturization of semiconductor devices. As shown by the arrows in FIG. 1, components of the high-K film 30 are diffused into the oxide film 20, further reducing the reliability of the oxide film 20.

The oxide film 20 is also vulnerable to the cleaning attacks used in the gate stack formation process and limited cleaning conditions must be used. Moreover, photo rework may cause loss of portions of the oxide film 20, leading to manufacturing restrictions.

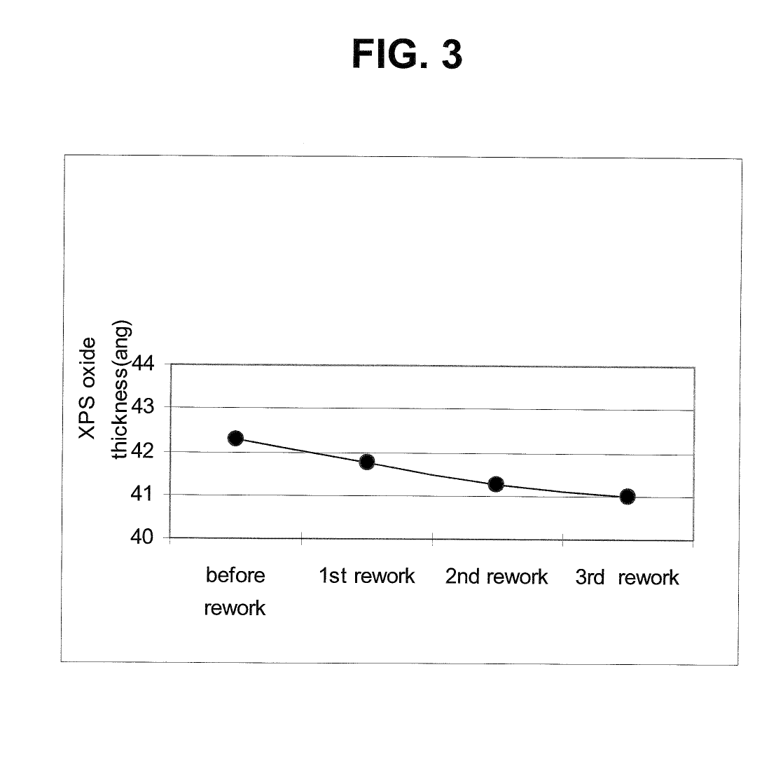

Referring to FIG. 3, data show thickness loss in angstroms of a film due to cleaning processes and several rework processes. As can be seen from FIG. 3, after each rework process, the thickness of the film markedly decreases.

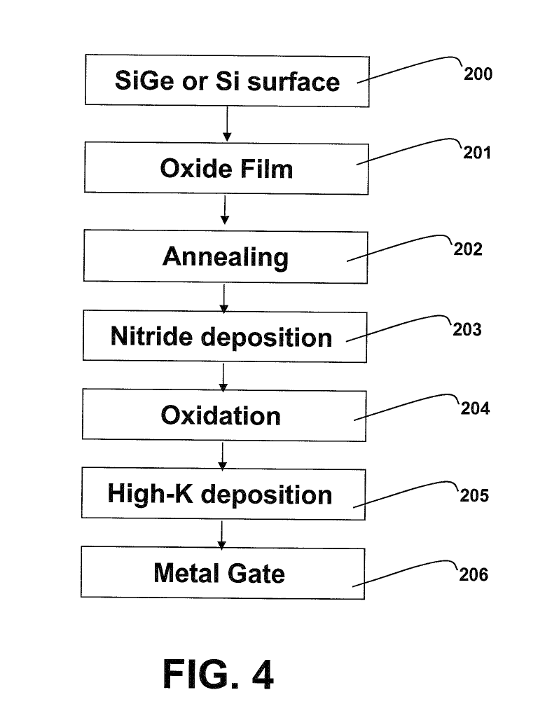

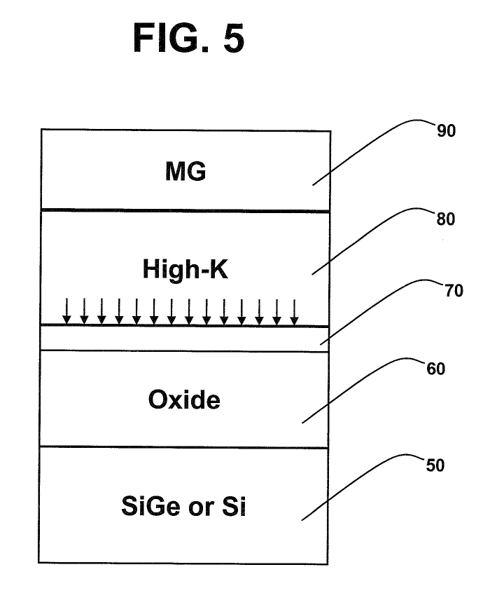

Referring to FIGS. 4 and 5, according to an embodiment of the present inventive concept, instead of performing the nitridation step 102 as shown in FIG. 2, the desired amount of nitrogen to reduce inversion thickness can be incorporated into the oxide film by depositing a nitride layer, such as, for example, silicon nitrides (SiN) or (SiHN), onto the oxide film 60 and oxidizing the nitride layer. Referring to FIG. 4, the nitride deposition 203 occurs after annealing 202, and can be done by, for example, a CVD process, such as plasma enhanced CVD (PECVD), low-pressure CVD (LPCVD), and atmospheric pressure CVD (APCVD), or an atomic layer deposition (ALD) process. After nitride deposition 203, the deposited nitride layer is oxidized to form a barrier layer 70 on the oxide film 60. The oxide film 60 is deposited by, for example, chemical vapor deposition, atomic layer deposition, or molecular layer deposition. As can be seen by the arrows in FIG. 5, the barrier layer 70 blocks the diffusion of the components of the high-K dielectric layer 80 into the oxide film 60. High-K film deposition and metal gate formation 205 and 206 is performed after oxidation 204 of the nitride layer

In addition, the high density nitrogen blocking layer 70 (e.g., a nitrogen concentration of about 10¹⁵/cm²) distributed at the top of oxide film 60 prevents diffusion of the components of the high-K dielectric layer 80 into the oxide film 60, further improving reliability of the resulting device.

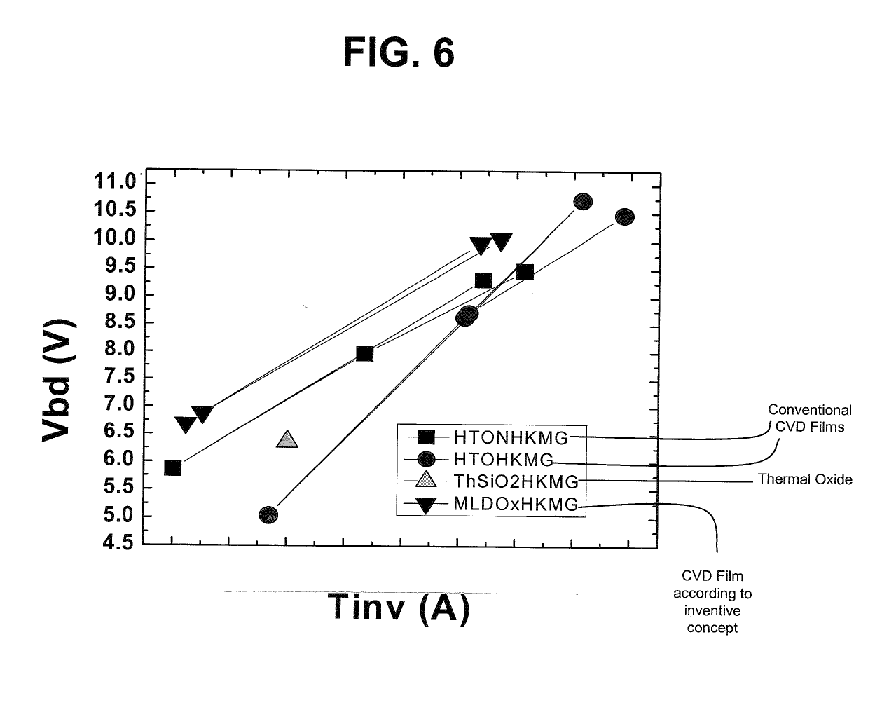

Referring to FIG. 6, to illustrate the improved reliability, the graph plots breakdown voltage (V_{bd}) versus inversion thickness (Tᵢₙᵥ) of different CVD oxide films, including a CVD oxide film formed in accordance with the embodiment of the present inventive concept shown in FIG. 5. As shown in FIG. 6, the CVD oxide film 60 according to the embodiment of the present inventive concept exhibits a higher breakdown voltage (approximately 6.5 volts (V)—approximately 10V) over a range of inversion thickness than each of the conventional films, including thermal oxide and the CVD film subject to nitridation according to the method described in FIG. 2. Accordingly, a semiconductor device manufactured in accordance with an embodiment of the present inventive concept exhibits the desired higher breakdown voltages at lower inversion thicknesses. According to this example, Tᵢₙᵥ is in units of angstroms.

Because thermally oxidized film is on the top of the film, it is more resistant to wet attacks than the CVD film 20. As a result, unlike the situation illustrated in FIG. 3, cleaning processes for removing particles and several rework processes can be performed without damaging or greatly reducing the thickness of the oxide film 60. The presence of the oxidized nitride layer 70 on a top surface of the oxide film 60 also allows for a thinner oxide film 60, for example, <about 30 Å, as compared to a thickness of the oxide film 20 of about 42 Å, while still maintaining good reliability even when a high-K dielectric film 80 is used.

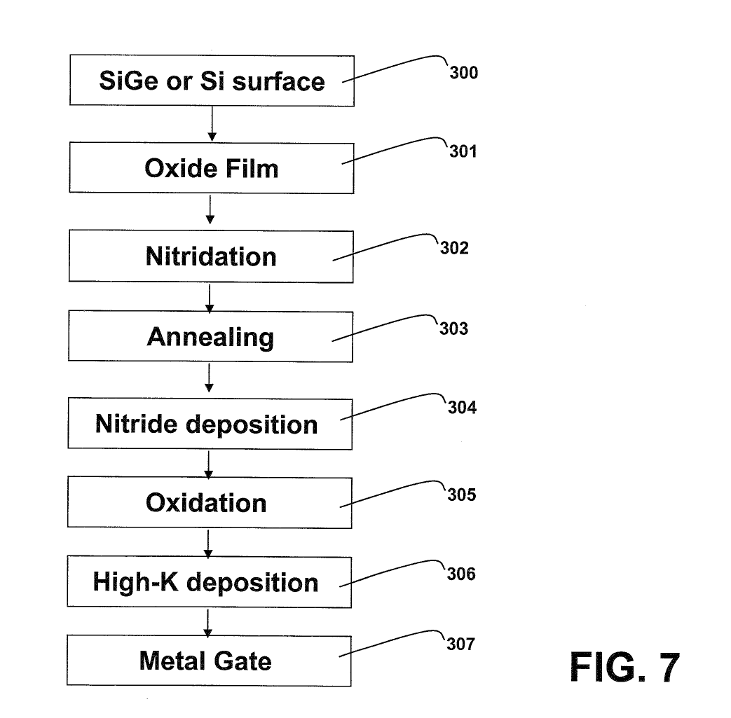

Referring to FIG. 7, a method for forming a metal oxide film according to another embodiment of the present inventive concept is shown. The method shown in FIG. 7 is similar to that shown in FIG. 4, except that the method shown in FIG. 7 includes a nitridation step 302 between oxide film deposition 301 and annealing 303.

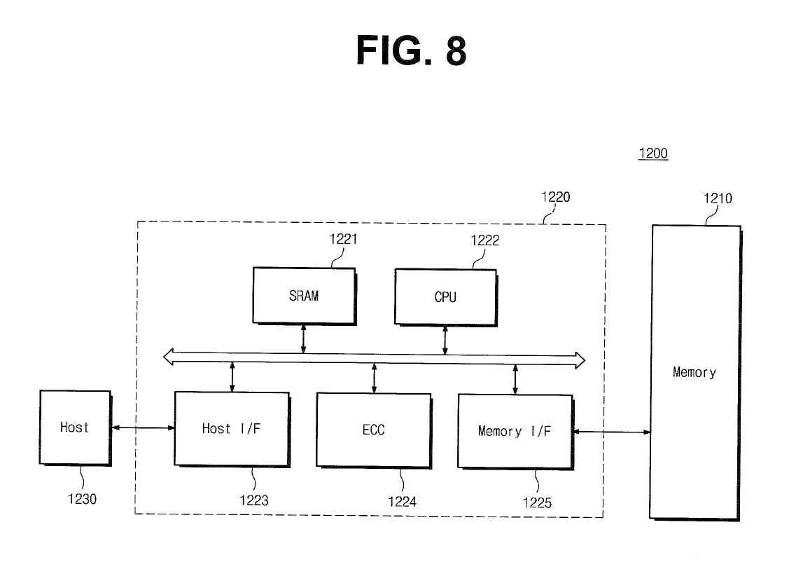

FIG. 8 is a block diagram of a memory card having a semiconductor device including a metal oxide film according to an embodiment of the inventive concept.

Referring to FIG. 8, a semiconductor memory 1210 including semiconductor devices with metal oxide films according to various embodiments of the inventive concept may be applicable to a memory card 1200. For example, the memory card 1200 includes a memory controller 1220 that controls data exchange between a host and the memory 1210. An SRAM 1221 may be used as a working memory of a central processing unit (CPU) 1222. A host interface (I/F) 1223 may have a data exchange protocol of the host connected to the memory card 1200. An error correction code (ECC) 1224 detects and corrects an error in data read from the memory 1210. A memory interface (I/F) 1225 interfaces with the memory 1210. The CPU 1222 performs an overall control operation for data exchange of the memory controller 1220.

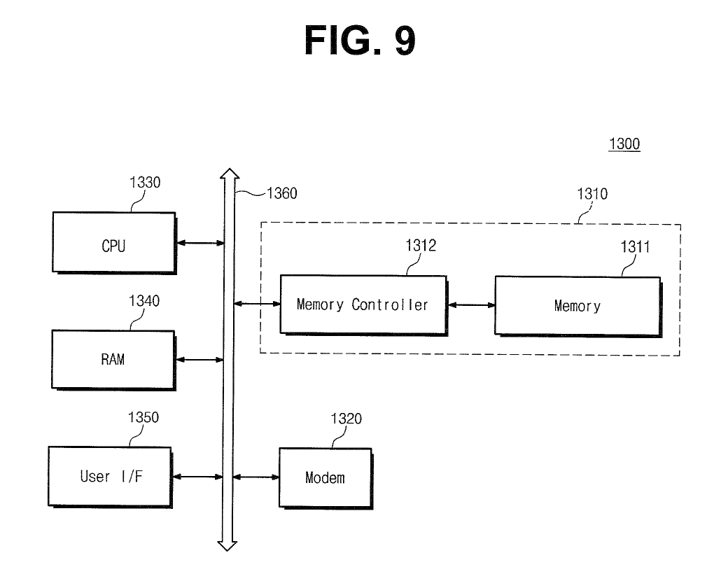

FIG. 9 is a block diagram of an information processing system using a semiconductor device including a metal oxide film according to an embodiment of the inventive concept.

Referring to FIG. 9, an information processing system 1300 may include a memory system 1310 having a semiconductor device including a metal oxide film according to an embodiment of the inventive concept. Examples of the information processing system 1300 include mobile devices and computers. For example, the information processing system 1300 includes a memory system 1310, a modem 1320, a central processing unit (CPU) 1330, a RAM 1340, and a user interface 1350 that are electrically connected to a system bus 1360. The memory system 1310 may include a memory 1311 and a memory controller 1312 and may have substantially the same configuration as the memory card 1200 of FIG. 8. Data processed by the CPU 1330 or data received from an external device may be stored in the memory system 1310. The information processing system 1300 may be provided for memory cards, solid state disks, camera image sensors, and other application chipsets. For example, the memory system 1310 may be configured using a solid state disk (SSD). In this case, the information processing system 1300 can store a large amount of data in the memory system 1310 stably and reliably.

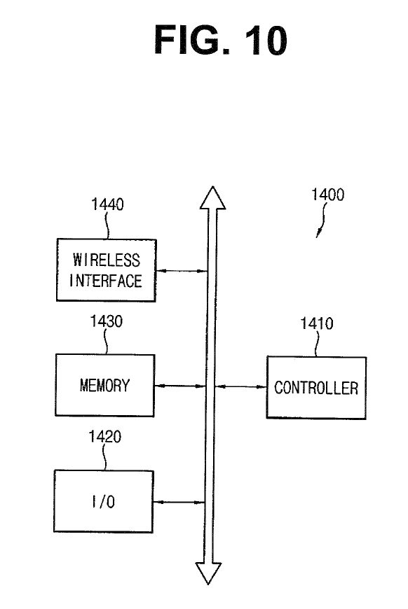

Referring to FIG. 10, an electronic device including a semiconductor device having a metal oxide film according to exemplary embodiments of the present inventive concept will be described. The electronic device 1400 may be used in a wireless communication device (e.g., a personal digital assistant, a laptop computer, a portable computer, a web tablet, a wireless telephone, a mobile phone and/or a wireless digital music player) or in any device capable of transmitting and/or receiving information via wireless environments.

The electronic device 1400 includes a controller 1410, an input/output (I/O) device 1420 (e.g., a keypad, a keyboard, and a display), a memory 1430 having a metal oxide film according to at least one embodiment of the present inventive concept, and a wireless interface 1440. The controller 1410 may include at least one of a microprocessor, a digital signal processor, or a similar processing device. The memory 1430 may be used to store commands executed by the controller 1410, for example. The memory 1430 may be used to store user data. The memory 1430 includes a semiconductor device having a metal oxide film according to at least one embodiment of the present inventive concept. The electronic device 1400 may utilize the wireless interface 1440 to transmit/receive data via a wireless communication network. For example, the wireless interface 1440 may include an antenna and/or a wireless transceiver. The electronic device 1400 according to exemplary embodiments may be used in a communication interface protocol of a third generation communication system, e.g., code division multiple access (CDMA), global system for mobile communications (GSM), north American digital cellular (NADC), extended-time division multiple access (E-TDMA) and/or wide band code division multiple access (WCDMA), CDMA2000.

Although exemplary embodiments of the present inventive concept have been described hereinabove, it should be understood that the present inventive concept is not limited to these embodiments, but may be modified by those skilled in the art without departing from the spirit and scope of the present inventive concept.

What is claimed is:

1. A method for forming a gate stack of a semiconductor device, comprising:
depositing a gate oxide layer on a channel region of a semiconductor substrate using chemical vapor deposition, atomic layer deposition or molecular layer deposition;
depositing a nitride layer on the gate oxide layer;
oxidizing the deposited nitride layer;
depositing a high-K dielectric layer on the oxidized nitride layer; and
forming a metal gate on the high-K dielectric layer.

2. The method according to claim 1, further comprising:
annealing the gate oxide layer prior to depositing the nitride layer.

3. The method according to claim 1, wherein the nitride layer is deposited by one of plasma enhanced chemical vapor deposition (PECVD), low pressure chemical vapor deposition (LPCVD) or atmospheric pressure chemical vapor deposition (APCVD).

4. The method according to claim 1, wherein the nitride layer is deposited by atomic layer deposition (ALD).

5. The method according to claim 1, wherein the semiconductor substrate is made of at least one of silicon (Si) and silicon germanium (SiGe).

6. The method according to claim 1, further comprising performing nitridation on the gate oxide layer after deposition of the gate oxide layer.

7. The method according to claim 1, wherein the nitride layer includes one of SiN or SiHN.

8. A gate stack of a semiconductor device, comprising:
a deposition gate oxide layer on a channel region of a semiconductor substrate;
an oxidized nitride layer on the gate oxide layer;
a high-K dielectric layer on the oxidized nitride layer; and
a metal gate on the high-K dielectric layer.

9. The gate stack according to claim 8, wherein the deposition gate oxide layer is one of a chemical vapor deposition, atomic layer deposition or molecular layer deposition gate oxide layer.

10. The gate stack according to claim 8, wherein the semiconductor substrate is made of at least one of silicon (Si) and silicon germanium (SiGe).

11. A semiconductor device, comprising:
a deposition gate oxide layer on a channel region of a semiconductor substrate;
an oxidized nitride layer on the gate oxide layer;
a high-K dielectric layer on the oxidized nitride layer; and
a metal gate on the high-K dielectric layer.

12. The semiconductor device according to claim 11, wherein the deposition gate oxide layer is one of a chemical vapor deposition, atomic layer deposition or molecular layer deposition gate oxide layer.

13. A computer system comprising the semiconductor device of claim 11, wherein the computer system is one of a personal computer (PC), a personal digital assistant (PDA), an MP3 player, a digital audio recorder, a pen-shaped computer, a digital camera, or a video recorder.

14. A system for transmitting or receiving data, the system comprising:
a device for storing a program; and
a processor in communication with the device, wherein the device comprises:
a deposition gate oxide layer on a channel region of a semiconductor substrate;
an oxidized nitride layer on the gate oxide layer;
a high-K dielectric layer on the oxidized nitride layer; and
a metal gate on the high-K dielectric layer.

15. The system according to claim 14, wherein the deposition gate oxide layer is one of a chemical vapor deposition, atomic layer deposition or molecular layer deposition gate oxide layer.

16. The system according to claim 14, wherein the system comprises at least one of a mobile system, a portable computer, a web tablet, a mobile phone, a digital music player, or a memory card.

17. A semiconductor memory card, comprising:
an interface part that interfaces with an external device;
a controller that communicates with the interface part and a semiconductor device via address and data buses, wherein the semiconductor device comprises:
a deposition gate oxide layer on a channel region of a semiconductor substrate;
an oxidized nitride layer on the gate oxide layer;
a high-K dielectric layer on the oxidized nitride layer; and
a metal gate on the high-K dielectric layer.

18. The semiconductor memory card according to claim 17, wherein the deposition gate oxide layer is one of a chemical vapor deposition, atomic layer deposition or molecular layer deposition gate oxide layer.
